(19) United States
(12) Patent Application Publication
(10) Pub. No.: US 2008/0057717 A1
(43) Pub. Date: Mar. 6, 2008

(54) SEMICONDUCTOR DEVICE MANUFACTURING METHOD

(75) Inventors: Tamotsu OWADA, Kawasaki (JP); Hirofumi WATATANI, Kawasaki (JP); Shirou OZAKI, Kawasaki (JP); Hisaya SAKAI, Kawasaki (JP); Kenichi YANAI, Kawasaki (JP); Naoki OHARA, Kawasaki (JP); Tadahiro IMADA, Kawasaki (JP); Yoshihiro NAKATA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/844,023

(22) Filed: Aug. 23, 2007

(30) Foreign Application Priority Data
Aug. 24, 2006 (JP) 2006-227329
Jun. 25, 2007 (JP) 2007-165825
Jul. 23, 2007 (JP) 2007-190672

(51) Int. Cl. H01L 21/311; H01L 21/4763

(52) U.S. Cl. 438/694; 438/623; 257/E21.249; 257/E21.495

(57) ABSTRACT

A semiconductor device manufacturing method that includes depositing a first insulating film on a semiconductor substrate, etching a part of the first insulating film, and performing UV irradiation to the first insulating film.

### CROSS-REFERENCE TO RELATED APPLICATIONS

This application is based upon and claims the benefit of priority from the prior Japanese Patent Application No. 2006-227329, filed on Aug. 24, 2006, Application No. 2007-165825, filed on Jun. 25, 2007, Application No. 2007-190672, filed on Jul. 23, 2007, the entire content of which is incorporated herein by reference.

### FIELD OF THE INVENTION

The present invention relates to a semiconductor device manufacturing method and, more particularly, to a method for forming an interlayer film of a semiconductor device having multilayer interconnections.

### DESCRIPTION OF THE PRIOR ART

The signal propagation velocity in multilayer interconnections of a semiconductor device is determined by wiring resistance and the parasitic capacitance between wires. Due to a recent increase in the integration of semiconductor devices, the spacing between wires has been decreasing resulting in an increase in parasitic capacitance between wires. A device using Cu with a resistance lower than that of Al as a wiring material has been utilized in order to avoid wiring delay and increase propagation velocity.

Also, efforts have been made toward practical use of a semiconductor device with a wiring capacitance reduced by using a material with a dielectric constant lower than that of SiO₂ (low-dielectric-constant material) for an interlayer insulating layer. The relative dielectric constant of SiO₂ is about 4.0 to 4.5. A material with a dielectric constant lower than that of SiO₂ is generally called a low-dielectric-constant material. The use of a low-dielectric-constant material as an interlayer insulating film also requires suppressing leakage current between wires, keeping mechanical strength at or above a certain level, and the like.

As low-dielectric-constant materials, known materials are an organic polyarylene film or a polyarylether film formed by a spin-on process, an inorganic hydrogen silsesquioxane (HSQ) film, methyl silsesquioxane (MSQ) film, or an HSQ-MSQ hybrid material, and a silicon oxycarbide (SiOC) film formed by chemical vapor deposition (hereinafter referred to as CVD) using an organosiloxane material. There is also available a porous silica film with a dielectric constant reduced by forming pores in an insulating material.

Patent Documents 1 to 3 below each disclose a manufacturing process for a semiconductor device using a low-dielectric-constant interlayer film and Cu wiring. Non-patent Document 1 discloses that if a low-dielectric-constant film is exposed to plasma after formation, a damaged layer is formed at its surface.

Patent Document 1: Japanese Patent Laid-Open No. 2000-68274

Patent Document 2: Japanese Patent Laid-Open No. 2000-174019

Patent Document 3: Japanese Patent Laid-Open No. 2004-193453

Non-Patent Document 1: Removal of Plasma-Modified Low-k Layer Using Dilute HF: Influence of Concentration (Electrochemical and Solid-State Letters, Volume 8, Issue 7, pp. F21-F24 (2005))

It is expected that in the future, the spacing between wires in a semiconductor device will become smaller, and signal propagation delay will become a significant factor which affects the performance of the semiconductor device. Under the above-described circumstances, a low-dielectric-constant material used in an interlayer insulating film is required to achieve a stably low dielectric constant, a good inter-wire leakage characteristic, and the like.

### SUMMARY OF THE INVENTION

The present invention is directed to a semiconductor device manufacturing method that includes depositing a first insulating film over a semiconductor substrate, etching a part of the first insulating film, and performing UV irradiation to the first insulating film.

### BRIEF DESCRIPTION OF THE DRAWINGS

FIGS. 1A to 1G are sectional views of respective steps showing a manufacturing method in accordance with an embodiment of the present invention;

FIG. 2 is a view showing the structure of a sample for evaluating a device manufactured by the method in FIGS. 1A to 1G;

FIG. 3 is a graph showing the relative dielectric constants of samples manufactured by the method in FIGS. 1A to 1G;

FIG. 4 is a graph showing the I-V characteristics of the samples manufactured by the method in FIGS. 1A to 1G;

FIG. 5 is a graph showing the refractive indexes of the samples manufactured by the method in FIGS. 1A to 1G;

FIG. 6 is a graph showing the result of performing desorption analysis on the samples manufactured by the method in FIGS. 1A to 1G;

FIG. 7 is a graph showing the relative dielectric constants of samples manufactured by the method in FIGS. 1A to 1G;

FIGS. 8A to 8F are sectional views of respective steps showing a manufacturing method in accordance with an additional embodiment of the present invention;

FIG. 9 is a view showing a vapor process in accordance with a second embodiment of the present invention;

FIG. 10 is a graph showing the relative dielectric constants of samples manufactured by the method in FIGS. 1A to 1G;

FIG. 11 is a graph showing leakage currents in samples manufactured by the method in FIGS. 1A to 1G; and

FIG. 12 is a graph showing the relative dielectric constants of samples manufactured by the method in FIGS. 1A to 1G.

### PREFERRED EMBODIMENT

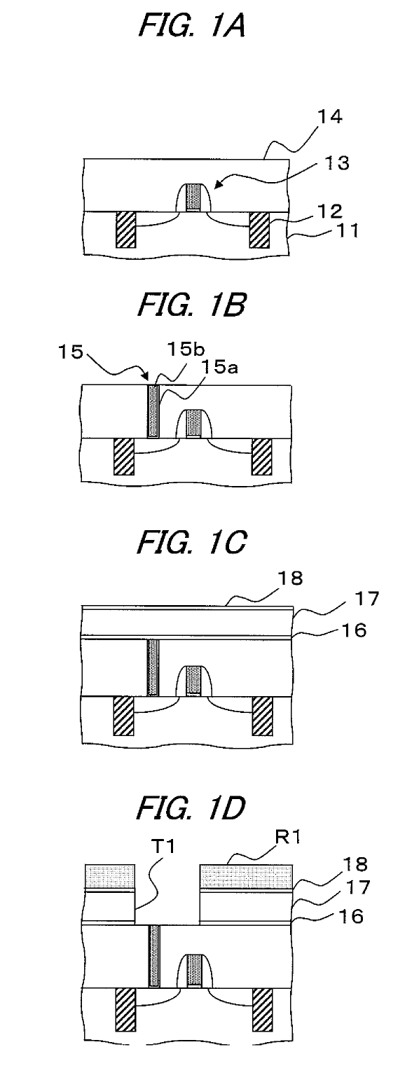

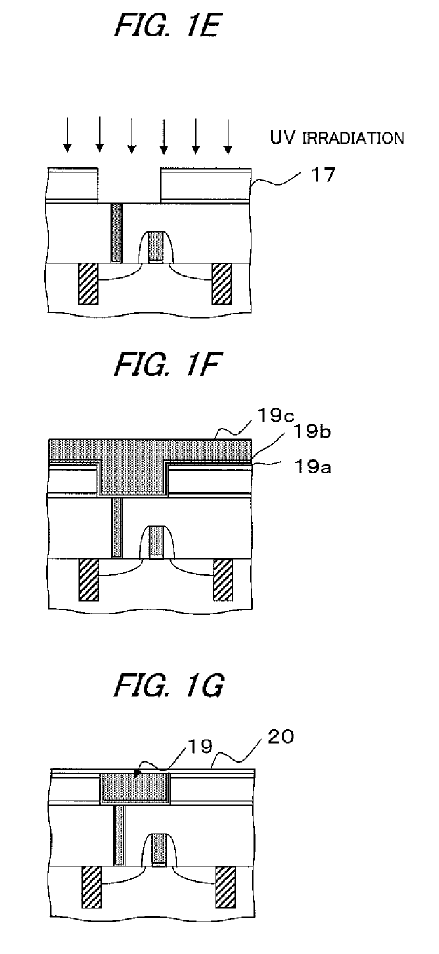

FIGS. 1A to 1G are sectional views of respective steps showing a manufacturing method in accordance with an embodiment of the present invention.

As shown in FIG. 1A, an element isolating oxide film 12 is formed on the surface of a semiconductor substrate 11 by STI. An MOS transistor 13 is formed in an active region demarcated by the element isolating oxide film 12. The MOS transistor 13 includes a source electrode, a drain electrode, and a gate electrode. As described for the preferred embodiment, the MOS transistor 13 has a gate length of about 65 nm and a gate insulating film with a thickness of 2 nm. A low-resistivity metal silicide layer of Co-silicide, Ni-silicide, or the like may be formed on the surfaces of the source electrode, drain electrode, and gate electrode. A first interlayer insulating film 14 made of PSG with a thickness of 1.5 μm is deposited by CVD such that the MOS transistor 13 is covered with the first interlayer insulating film 14, and the surface thereof is planarized by CMP.

As shown in FIG. 1B, a contact plug 15 which is composed of a TiN film 15a and a W film 15b is formed in the first interlayer insulating film 14. More specifically, the TiN film 15a is deposited such that the inner wall surface of a contact hole formed by etching the first interlayer insulating film 14 is covered with the TiN film 15a, and the W film 15b is deposited thereon to fill up the contact hole. After that, the TiN film 15a and W film 15b deposited on the first interlayer insulating film 14 are removed by CMP.

As shown in FIG. 1C, an etching stopper film 16 which is made of SiC is formed to a thickness of 50 nm by CVD with tetramethylsilane gas supplied at 1,000 sccm and CO₂ supplied at 2,500 sccm at a radio frequency power of 500 W, a low frequency power of 400 W, and a pressure of 2.3 Torr. A SiO₂ film, a SiN film, or the like can be used as the etching stopper film other than a SiC film. An MSQ-HSQ hybrid porous silica film (NCS from Catalysts & Chemicals Industries Co., Ltd.) is deposited as a first low-dielectric-constant interlayer film 17 to a thickness of 250 nm over the entire etching stopper film 16 by a spin-on process. After the deposition of the first low-dielectric-constant interlayer film 17, baking is performed at 250° C. for 1 minute. Next, heat treatment is performed at a substrate temperature of 400° C. for 30 minutes in a nitrogen atmosphere. A CMP sacrificial film 18 which is made of a SiO₂ film is deposited to a thickness of 30 nm on the first low-dielectric-constant interlayer film 17. A SiN film, a SiC film, or the like can be used as the CMP sacrificial film 18 other than a SiO₂ film.

As shown in FIG. 1D, after a photoresist film R1 is applied to the CMP sacrificial film 18, it is patterned by a photolithographic process to form a wiring trench pattern T1. The CMP sacrificial film 18 and first low-dielectric-constant interlayer film 17 are etched using the patterned photoresist film R1 as a mask, thereby forming a wiring trench. The etching is performed by RIE using CF₄ as an etching gas. The RF power is 250 W, and the chamber pressure is 20 mTorr. The etching stopper film 16 is etched using, e.g., CH₂F₂ as an etching gas at an RF power of 100 W and a pressure of 20 mTorr. The photoresist mask R1 is then removed by ashing. Post treatment using a chemical solution and water cleaning are performed, thereby removing residues and the like.

Referring to FIG. 1F, the wiring trench formed in the first low-dielectric-constant interlayer film 17 is exposed to UV irradiation in a vacuum chamber. The irradiation is performed at a chamber pressure of 10 Torr, a UV intensity of 350 mW/cm², and a substrate heater temperature of 230° C. for 10 minutes in a He gas atmosphere.

As shown in FIG. 1F, a Cu diffusion preventing film 19a which is made of, e.g., a Ta film is formed to a thickness of 30 nm by, e.g., sputtering such that the inner walls of the wiring trench and the surface of the CMP sacrificial film 18 is covered with the Cu diffusion preventing film 19a. Prior to the formation of the Cu diffusion preventing film 19a, a process may be performed of keeping the substrate in a H₂ atmosphere at a substrate temperature of 200° C. and a pressure of 1.5 Torr for 1 or 2 minutes. A Cu seed layer 19b with a thickness of 30 nm is formed by the sputtering, and a Cu wiring layer 19c with a thickness of 500 nm is formed by plating on the Cu seed layer 19b.

As shown in FIG. 1G, parts of the Cu wiring layer 19c, Cu seed layer 19b, and Cu diffusion preventing film 19a which are deposited on the CMP sacrificial film 18 are removed by CMP, thereby forming a first wiring layer 19 in the first low-dielectric-constant interlayer film 17. After that, a Cu diffusion preventing cap film 20 which is made of, e.g., SiC is formed to a thickness of 50 nm such that the upper surface of the first wiring layer 19 and that of the CMP sacrificial film 18 are covered with the Cu diffusion preventing cap film 20. A SiN film or the like can be used as the Cu diffusion preventing cap film other than a SiC film.

With the steps shown in FIGS. 1A to 1G, in the first low-dielectric-constant interlayer film 17, the UV irradiation after the etching step repairs etching-damage to the low-dielectric-constant interlayer and suppresses an increase in dielectric constant. The UV irradiation also makes it possible to suppress a leakage current between wires.

As the low-dielectric-constant film, there can be used a polyarylene film, a polyarylether film, a hydrogen silsesquioxane film, a methyl silsesquioxane film, a silicon oxycarbide film, or a film obtained by stacking these films.

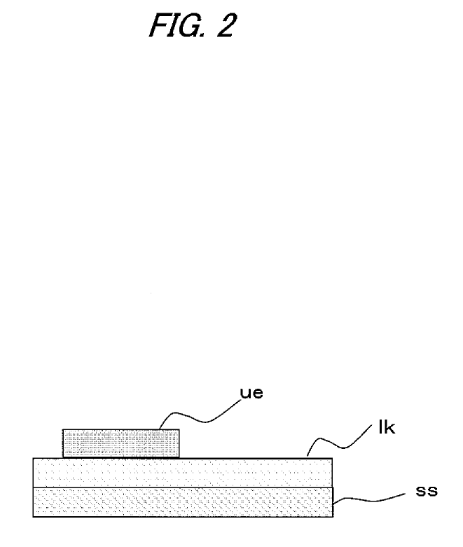

FIG. 2 is a sectional view showing the structure of a sample for measuring the dielectric constant of a device manufactured by the method in FIGS. 1A to 1G. Sample (A) is a sample for measuring the dielectric constant of a low-dielectric-constant film which is deposited and remains intact, i.e., which is not subjected to an etching step.

An MSQ-HSQ hybrid porous silica film was deposited as a low-dielectric-constant film lk on a low-resistivity silicon substrate ss doped with impurities. The MSQ-HSQ hybrid porous silica film was formed using a spin-on process. More specifically, NCS (registered trademark) from Catalysts & Chemicals Industries Co., Ltd. was applied over the entire low-resistivity silicon substrate ss, baking was performed at 250° C. for 1 minute, and heat treatment was performed at 400° C. for 30 minutes in a nitrogen atmosphere in a diffusion furnace.

An Au upper electrode ue was formed on the low-dielectric-constant film lk. The Au upper electrode ue was formed by arranging a metal mask which has a circular opening on the surface of the low-dielectric-constant film lk and forming an Au film to a thickness of 100 nm by vapor deposition. The Au upper electrode ue was formed to have a diameter of 1 mm. As for sample (A) thus formed, the relative dielectric constant of the low-dielectric-constant film was calculated by capacitance measurement using an LCR meter. The measurement result showed that the relative dielectric constant of the low-dielectric-constant film was about 2.3.

Next, sample (B) was formed to check a change in the characteristics of a low-dielectric-constant film lk caused by an etching step. A step of forming sample (B) is as follows. A low-dielectric-constant film lk was formed to a thickness of 100 nm on a low-resistivity silicon substrate ss under the same conditions as those for sample (A), and then the whole surface of the low-dielectric-constant film lk was etched and 50 nm of the film were removed. At the time of the etching, reactive ion etching (hereinafter referred to as RIE) using CF₄ gas was performed at an RF power of 250 W and a pressure of 20 Torr. After that, an Au upper electrode ue was formed on the low-dielectric-constant film lk.

As for sample (B) thus formed, the relative dielectric constant of the low-dielectric-constant film lk was measured. The relative dielectric constant was 3.0, which was higher than that of sample (A) not subjected to an etching step.

A step of forming sample (C) is as follows. A low-dielectric-constant film lk was deposited to a thickness of 100 nm on a low-resistivity silicon substrate ss, and then the low-dielectric-constant film lk was etched and 50 nm of the film were removed. The low-dielectric-constant film lk was UV-irradiated. The irradiation was performed at a chamber pressure of 10 Torr, a UV irradiation intensity of 350 mW/cm², and a substrate heater temperature of 230° C. for 10 minutes in a He gas atmosphere, using a high-pressure mercury lamp as a UV light source. An Au upper electrode ue was formed on the low-dielectric-constant film lk. UV light emitted from the high-pressure mercury lamp has a broad band of wavelengths ranging from 150 nm to 400 nm.

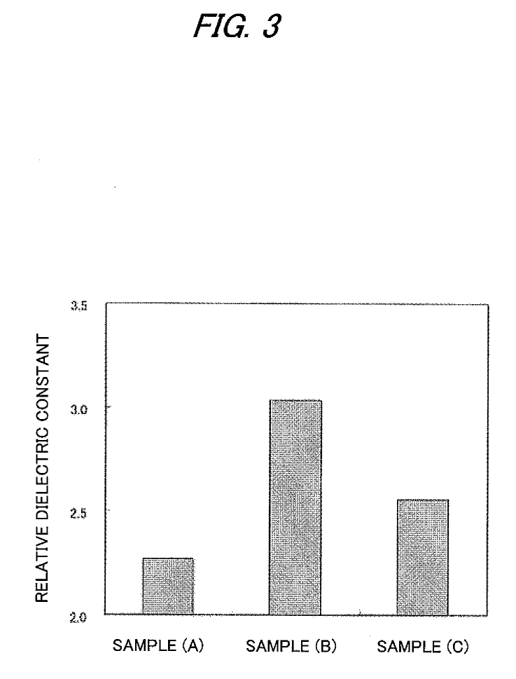

As for sample (C) thus formed, the relative dielectric constant of the low-dielectric-constant film lk was measured. The relative dielectric constant was 2.5. The relative dielectric constant is lower than that of sample (B), 3.0. FIG. 3 is a graph showing the relative dielectric constants of the samples. The ordinate represents relative dielectric constant.

The UV irradiation of the low-dielectric-constant film with the dielectric constant increased after the etching step reduced the dielectric constant.

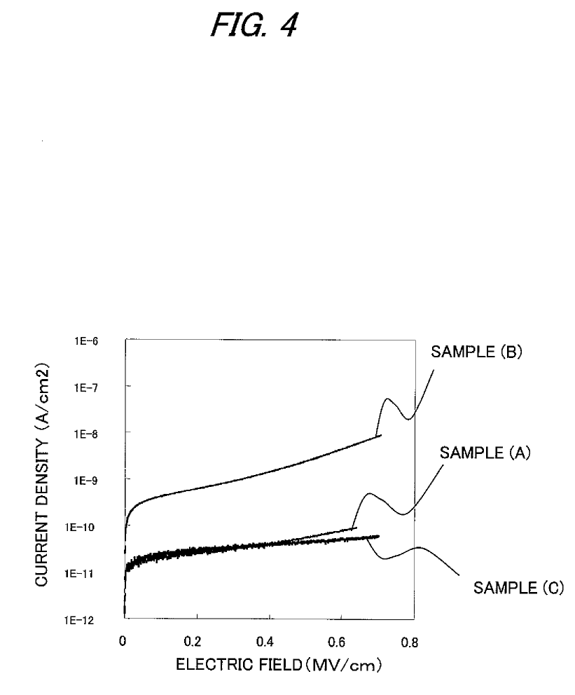

The leakage current characteristic of each of samples (A), (B), and (C) (i.e., the value of a current which leaked and flowed through the low-dielectric-constant film upon application of a voltage between the low-resistivity silicon substrate ss and Au upper electrode ue) was measured. FIG. 4 is a graph showing the I-V characteristics of the samples. The abscissa indicates electric field (MV/cm) while the ordinate indicates current density (A/cm²). In sample (A), a leakage current of 4.10E⁻¹⁰ mA/cm² was generated when the electric field was 0.4 MV/cm. It was found, as for sample (B), that the value of a generated leakage current was 1.46E⁻⁹ mA/cm² when the electric field was 0.4 MV/cm, which was an increase compared to sample (A). It was confirmed, as for sample (C), that the value of a generated leakage current was 3.85E⁻¹¹ mA/cm² when the electric field was 0.4 MV/cm, which was a decrease compared to sample (B). This value is almost equivalent to that of sample (A).

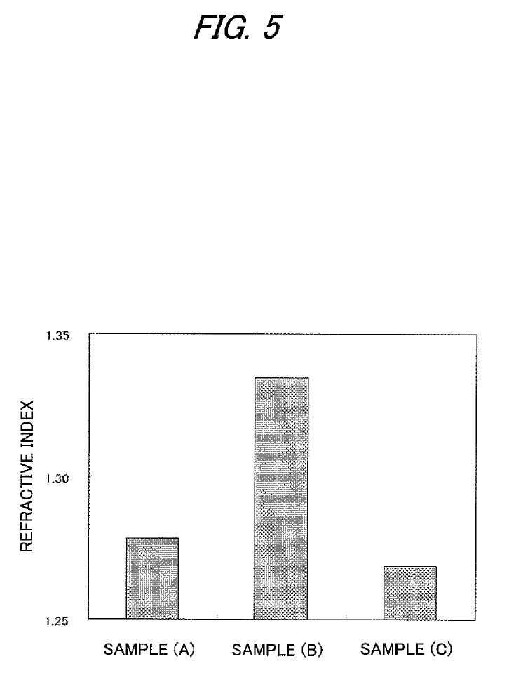

FIG. 5 is a graph showing the refractive indexes of the samples. The ordinate indicates the refractive index of a low-dielectric-constant film. Sample (A) exhibited a refractive index of 1.275. Sample (B) exhibited a refractive index of 1.33, which was an increase compared to sample (A). Sample (C) exhibited a refractive index of 1.26, which was a decrease compared to sample (B).

Absorption of moisture by an etching-damaged layer can be considered to be a cause of the higher refractive index of sample (B). It is conceivable that the restorative decrease of the refractive index of sample (C) to 1.26 is due to the UV irradiation repairing etching damage to the layer. Namely, a hydrophobic surface which the film had originally had was regenerated, and the hygroscopicity was reduced.

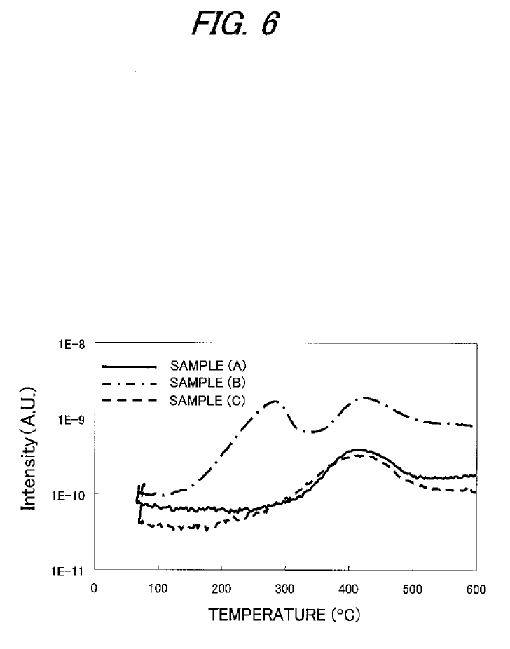

FIG. 6 is a graph showing the result of performing desorption analysis on samples. The desorption analysis used a thermal desorption spectroscopy (hereinafter referred to as TDS) apparatus. Samples (A), (B), and (C) were each heated with infrared rays in a vacuum, and emitted gas was measured by a quadrupole mass spectrometer. The abscissa indicates substrate heating temperature (° C.), and the ordinate indicates the intensity for a gas with a molecular weight of 18. In the measurement of sample (B), peaks of the intensity for the gas with the molecular weight of 18 were confirmed at heating temperatures of about 280° C. and 420° C. This is presumably due to emission of water (H₂O). The low-dielectric-constant film lk absorbed more moisture in sample (B) than in sample (A). It is conceivable, as for in sample (C) subjected to the UV irradiation after the etching, that the hygroscopicity of the low-dielectric-constant film lk was reduced.

Of low-dielectric-constant materials, ones which are water-repellent are generally considered desirable. This is because the relative dielectric constant of water is as high as 88, and absorption of moisture by a low-dielectric-constant film increases its dielectric constant. In order to suppress an increase in the dielectric constant of a low-dielectric-constant film caused by moisture absorption, for example, the MSQ-HSQ hybrid porous silica films used in the above experiment were each formed such that the surface terminated with, e.g., Si—H or Si—CH₃, which is hydrophobic.

However, it is conceivable that a low-dielectric-constant film subjected to etching has a damaged layer of some kind. For example, at the surface of an MSQ-HSQ hybrid porous silica film, an intrinsic chemical bond may be broken, and a hydrophilic Si—OH group may be formed. In this case, moisture in the air sticks to the film surface, and consequently the dielectric constant increases.

It is conceivable that the UV irradiation of the etching-damaged layer removed a Si—OH group at the surface of the low-dielectric-constant film and reduced the water absorbability at the surface.

The detailed conditions at the time of UV irradiation will now be described.

(a) Substrate Temperature at the Time of UV Irradiation

As shown in FIG. 1B, in a manufacturing process for multilayer interconnection, an underlying wiring layer is formed, and then a low-dielectric-constant interlayer film is formed all over the underlying wiring layer. A trench is formed in the low-dielectric-constant interlayer film to reach the underlying wiring layer. The underlying wiring layer is exposed at the bottom of the trench. It was found that if UV irradiation was performed at this point in the process, a roughness occurred at a Cu surface of the underlying wiring layer at a certain semiconductor substrate temperature or higher.

Accordingly, the present inventor has confirmed that if UV irradiation is performed while controlling a semiconductor substrate temperature at the time of UV irradiation to 25° C. to 300° C., it is possible to repair etching damage while preventing a roughness at a Cu surface.

(b) Atmospheric gas for UV Irradiation

In a manufacturing process for multilayer interconnection, if a contact hole is formed in a low-dielectric-constant interlayer film, and UV irradiation is performed in the air while the surface of underlying Cu wiring is exposed, the surface of underlying Cu wiring is oxidized. UV irradiation was performed under reduced pressure conditions to prevent oxidation of Cu wiring. More specifically, it is desirable to perform UV irradiation under the condition that the concentration of oxygen is not more than 50 ppm. With these conditions, etching damage in a low-dielectric-constant interlayer film could be repaired without oxidizing Cu wiring, in a UV irradiation step.

To prevent oxidation of the surface of underlying Cu wiring and to improve a roughness at the Cu surface, it is desirable to perform UV irradiation in an atmosphere of an inert gas such as He, Ar, or N₂. This is because prevention of blowing-up of Cu wiring requires suppressing a rise in the temperature of a semiconductor substrate, and He gas, in particular, has high thermal conductivity and a strong effect of cooling a semiconductor substrate. UV irradiation is preferably performed at a substrate temperature of 25° C. to 300° C. and a pressure of 50 mTorr to 50 Torr if an atmospheric gas of He is used. The atmosphere for the UV irradiation may comprise a mixed gas of He, Ar, and N₂.

(c) Processing Time for UV Irradiation

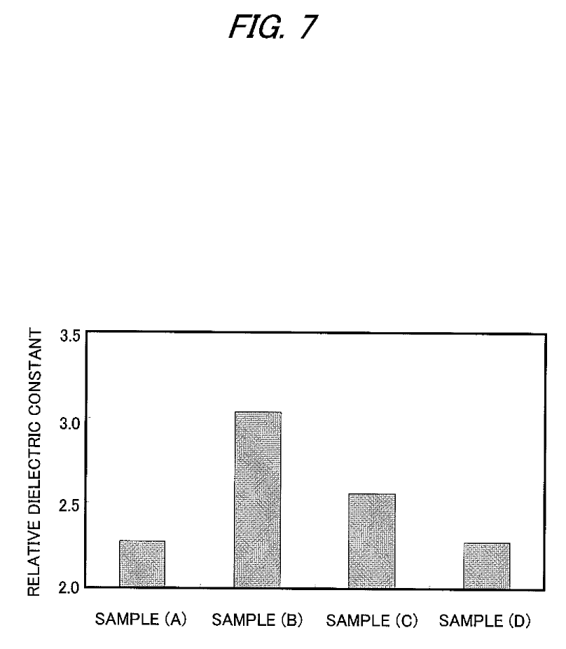

Sample (D) was formed to check the degree to which repair to damage generated in a low-dielectric-constant film by an etching step varied depending on UV irradiation time. Sample (D) was formed under the same conditions as those for sample (C) in FIG. 2. In contrast to the UV irradiation time of sample (C), 10 minutes, sample (D) was UV-irradiated for 15 minutes. FIG. 7 is a graph showing the relative dielectric constants of the samples. Sample (C) exhibited the relative dielectric constant of 2.5 while sample (D) exhibited a relative dielectric constant of 2.3. This value of the relative dielectric constant was almost equivalent to that of sample (A). It was confirmed from this that the dielectric constant of a low-dielectric-constant film subjected to an etching step can be returned to a state before the etching step by UV irradiation.

### Additional Embodiment of the Present Invention

A case will be described where a second wiring layer is formed after the steps shown in FIGS. 1A to 1G.

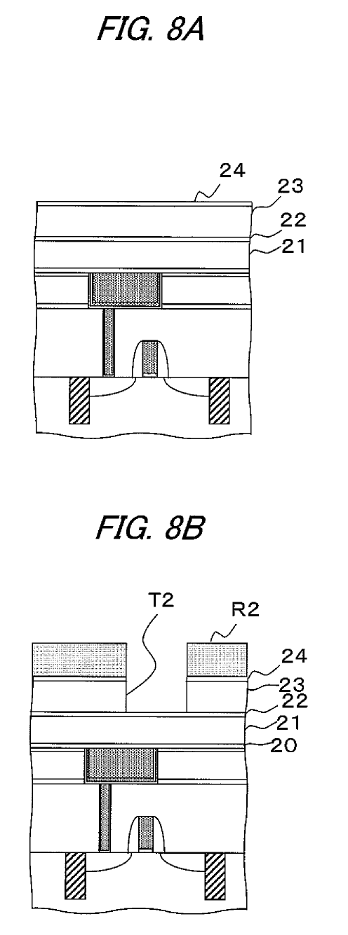

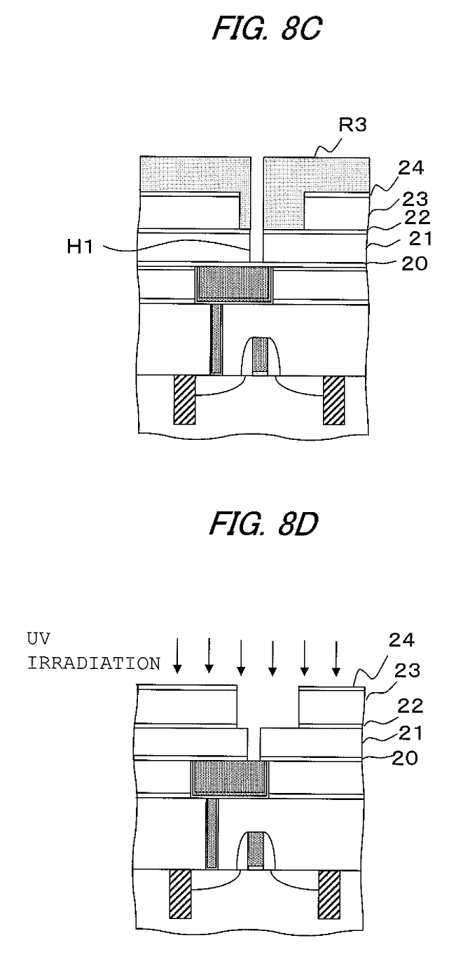

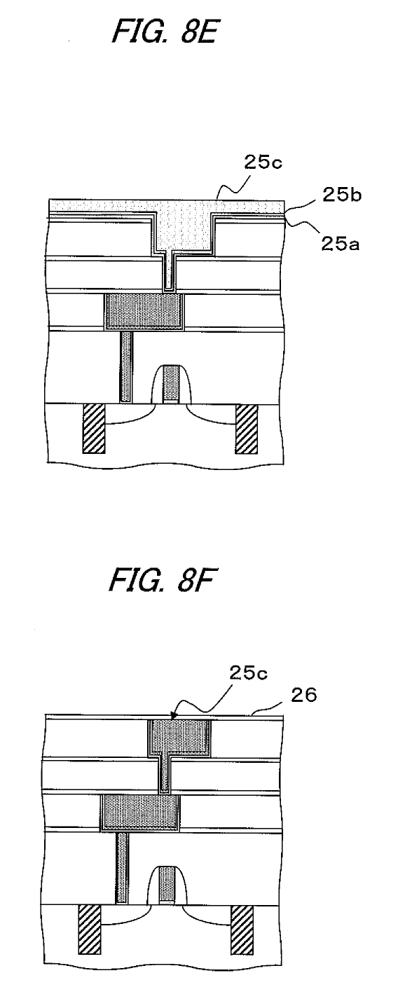

FIGS. 8A to 8F are sectional views of respective steps showing a manufacturing method according to an additional embodiment of the present invention.

As shown in FIG. 8A, an MSQ-HSQ hybrid porous silica film is formed as a second low-dielectric-constant interlayer film 21 to a thickness of 250 nm on a Cu diffusion preventing cap film 20. The formation of the second low-dielectric-constant interlayer film 21 is performed under the same conditions as those for the first low-dielectric-constant interlayer film 17. A middle stopper film 22 which is made of, e.g., a SiC film is formed to a thickness of 30 nm on the second low-dielectric-constant interlayer film 21. A SiO₂ film, a SiN film, or the like can be used as the middle stopper film other than a SiC film. A third low-dielectric-constant interlayer film 23 is formed to a thickness of 170 nm on the middle stopper film 22. A CMP sacrificial film 24 which is made of, e.g., a SiO₂ film is formed to a thickness of about 50 nm on the third low-dielectric-constant interlayer film 23. A SiN film, a SiC film, or the like can be used as the CMP sacrificial film 24 other than a SiO₂ film.

As shown in FIG. 8B, after a photoresist R2 is applied, it is patterned by a photolithographic process to form a wiring trench pattern T2. The CMP sacrificial film 24 and third low-dielectric-constant interlayer film 23 are etched to form a wiring trench, using the photoresist R2 patterned with the wiring trench pattern as a mask. The etching is performed until the middle stopper film 22 is exposed.

As shown in FIG. 8C, after the photoresist mask R2 is removed by ashing, a photoresist R3 is deposited and patterned by a photolithographic process to form a contact hole pattern H1. The middle stopper film 22 and second low-dielectric-constant interlayer film 21 are etched using the photoresist R3 patterned with the contact hole pattern. The etching of the middle stopper film 22 is performed at an RF power of 100 W and a pressure of 20 mTorr using, e.g., CH₂F₂ as an etching gas.

As shown in FIG. 8D, after the photoresist R3 is removed by ashing, the etching stopper film 20 is etched and removed, and the upper surface of a first wiring layer 19 is exposed, thereby forming a contact hole. The etching of the etching stopper film 20 is performed at an RF power of 100 W and a pressure of 20 mTorr using, e.g., CH₂F₂ as an etching gas.

The third low-dielectric-constant interlayer film 23 with the wiring trench formed therein and the second low-dielectric-constant interlayer film 21 with the contact hole formed therein are UV-irradiated. The UV irradiation is performed at a chamber pressure of 10 Torr, a UV intensity of 350 mW/cm², and a substrate heater temperature of 230° C. for 10 minutes in a He gas atmosphere.

As shown in FIG. 8E, a Cu diffusion preventing film 25a which is made of, e.g., a Ta film, a Cu seed layer 25b, and a Cu wiring layer 25c are sequentially formed such that the inner walls of the wiring trench and contact hole are covered with these layers. Prior to the formation of the Cu diffusion preventing film 25a, a step may be performed of removing an oxide film formed at a Cu surface of the first wiring layer 19. The oxide film at the Cu surface is reduced by keeping the oxide film in a H₂ atmosphere at a substrate temperature of 200° C. and a pressure of 1.5 Torr for 1 or 2 minutes.

As shown in FIG. 8F, after parts of the Cu wiring layer 25c, Cu seed layer 25b, and Cu diffusion preventing film 25a which are deposited on the CMP sacrificial film 24 are removed by CMP, a Cu diffusion preventing cap film 26 which is made of, e.g., a SiC film is formed to a thickness of about 50 nm, thereby completing a second wiring layer 25 (including a contact plug leading to the first wiring layer 19).

FIGS. 5A to 8F describe the steps of first etching the second and third low-dielectric-constant interlayer films 21 and 23 to form a wiring trench and then etching the films to form a contact hole. The additional embodiment of the present invention is not limited thereto. Various steps have been proposed and implemented for a dual-damascene process, and the present invention, of course, can be applied to a step of first performing etching to form a contact hole and then performing etching to form a wiring trench. The present invention can also be applied to a single damascene step of filling up a contact hole and a wiring trench by different CMP steps. In this case, UV irradiation, which repairs damage to a low-dielectric-constant interlayer film, is performed both after etching to form a contact hole and after etching to form a wiring trench.

In the above-described embodiments, the photoresists R1, R2, and R3 are removed by ashing using oxygen plasma. The surface of a low-dielectric-constant interlayer film may also be damaged by such an ashing step. UV irradiation is effective also in repairing damage generated in the ashing step. As such, it is more effective to perform UV irradiation after etching and ashing.

### Second Embodiment of the Present Invention

In this embodiment, an organic material is caused to adhere to the surface of a low-dielectric-constant film by performing an organic solvent vapor process, and then performing UV irradiation. This embodiment will be described with reference to FIGS. 1E and 8D.

Referring to FIG. 1E, a hexamethyldisilazane vapor process is performed for a low-dielectric-constant interlayer film 17 before UV irradiation.

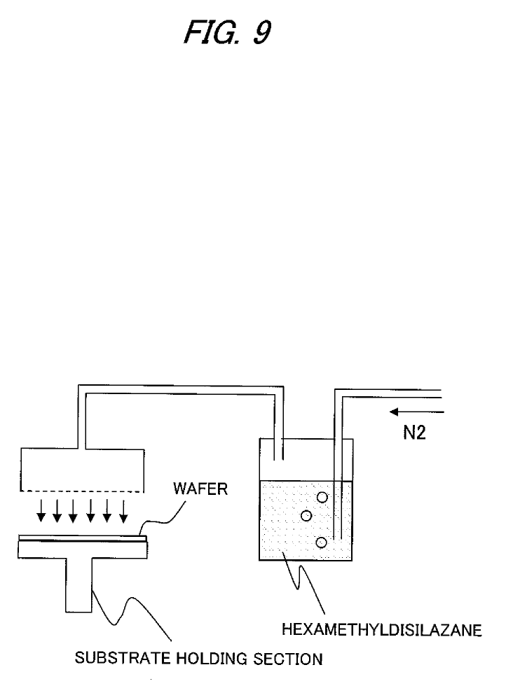

FIG. 9 is a view showing a vapor process according to the second embodiment of the present invention. A silicon wafer is arranged on a substrate holding section which is heated to 110° C., and hexamethyldisilazane is supplied to the wafer surface for 30 seconds by bubbling N₂ as a carrier gas.

As shown in FIG. 1E, UV irradiation is performed at a substrate heater temperature of 230° C. and a UV intensity of 350 mW for 10 minutes in a vacuum chamber.

The electromigration (hereinafter referred to as EM) resistance of a device which was fabricated by being subjected to the hexamethyldisilazane vapor process before the UV irradiation was evaluated. The result of device lifetime measurement by an accelerated test showed that the lifetime of the device subjected to the hexamethyldisilazane process increased to about 1.5 times beyond that of a device not subjected to the hexamethyldisilazane process.

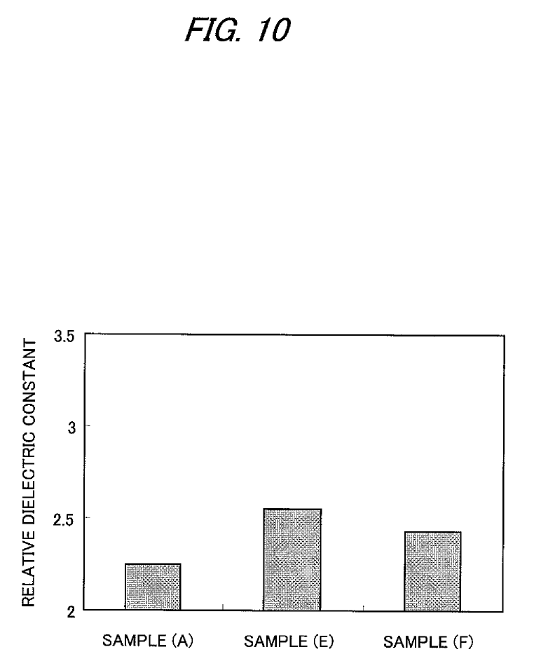

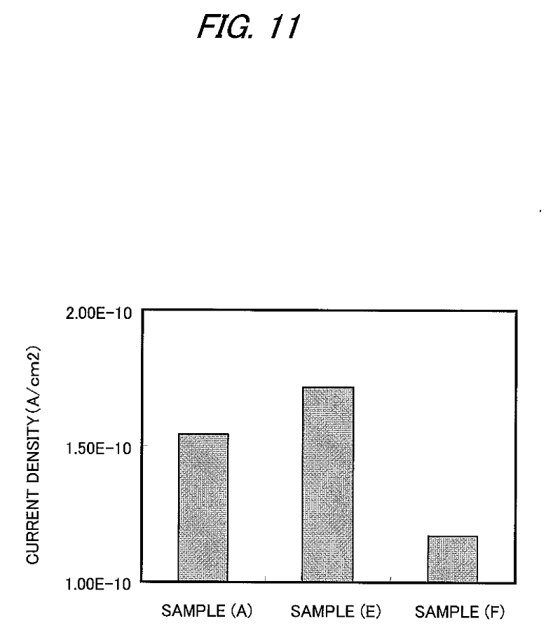

The UV irradiation after the hexamethyldisilazane process could effectively reduce the dielectric constant of a low-dielectric-constant film close to its original value. FIG. 10 is a graph showing the relative dielectric constants of samples manufactured by the method in FIGS. 1A to 1G. In FIG. 10, the ordinate indicates relative dielectric constant. Sample (E) is a sample which was subjected only to UV irradiation for 3 minutes without the hexamethyldisilazane process, after etching of the low-dielectric-constant film. Sample (F) is a sample which was subjected to the hexamethyldisilazane process and then to UV irradiation for 3 minutes, after etching of the low-dielectric-constant film. Sample (F) exhibited a relative dielectric constant lower than that of sample (E). Note that sample (A) is a sample which was not subjected to etching after deposition of a low-dielectric-constant film.

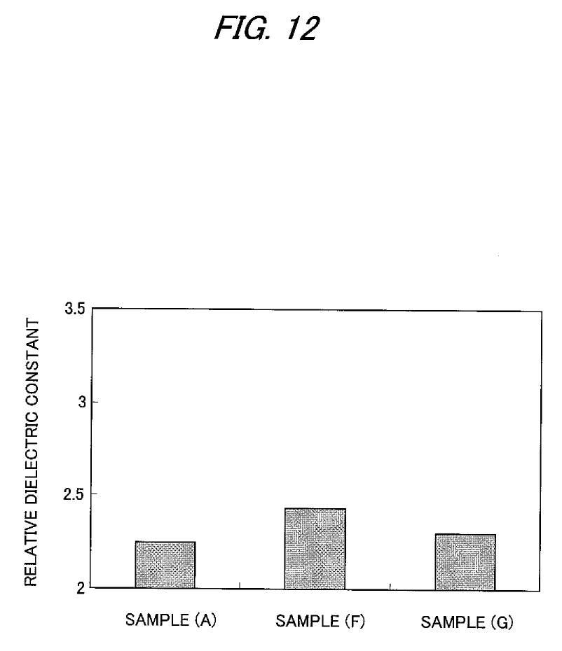

FIG. 11 is a graph showing leakage currents in the samples manufactured by the method in FIGS. 1A to 1G. In FIG. 11, the ordinate indicates a leakage current value when an electric field to be applied between electrodes is 0.4 MV/cm. Sample (F) exhibited a leakage current value lower than that of sample (E). The leakage current value of sample (F) was lower than that of sample (A) with no etching damage. After the UV irradiation, as shown in FIGS. 1F and 1G, a diffusion preventing film 19a, a Cu seed layer 19b, and a Cu wiring layer 19c are deposited, and a first wiring layer 19 is formed by CMP.

Referring to FIG. 8D, the hexamethyldisilazane vapor process is performed before UV irradiation. The UV irradiation is performed at a substrate heater temperature of 230° C. and a UV intensity of 350 mW for 10 minutes. After that, as shown in FIGS. 5E and 5F, a diffusion preventing film 25a, a Cu seed layer 25b, and a Cu wiring layer 25c are deposited, and a second wiring layer 25 is formed by CMP.

Even if a chemical solution containing a methyl group such as dimethylaminotrimethylsilane, tetramethydisilazane, divinyltetramethyldisilazane, cyclic dimethylsilazane, heptamethyldisilazane, or the like is used instead of hexamethyldisilazane, the same effects can be achieved. Instead of a method of causing such a chemical solution to adhere to the surface of a low-dielectric-constant film by a vapor process, a process may be performed of immersing a low-dielectric-constant film in a chemical solution containing a methyl group.

Among the above-listed chemical solutions containing a methyl group, dimethylaminotrimethylsilane exhibited an outstanding effect. FIG. 12 is a graph showing the relative dielectric constants of samples (A), (F), and (G). Sample (G) is a sample which was subjected to a dimethylaminotrimethylsilane vapor process and then to UV irradiation for 3 minutes, after etching of the low-dielectric-constant film. Sample (S) exhibited a relative dielectric constant lower than that of sample (F).

The present invention may include a step of exposing a low-dielectric-constant film which has undergone etching to a gas, such as ethylene gas, which contains C. For example, in this step, UV irradiation is performed after a low-dielectric-constant film is held in an environment at an ethylene gas flow rate of 500 sccm and a chamber pressure of 3 Torr for 1 minute, and C activated by UV light is supplied to the damaged low-dielectric-constant film. Alternatively, ethylene gas may be added to an atmosphere at the time of UV irradiation.

An organosilane gas such as tetramethylcyclotetrasiloxane, tricyclotetrasiloxane, dimethylphenylsilazane, trimethylsilylacetylene, or the like can be used as the gas for supplying C other than a hydrocarbon gas such as ethylene gas or acetylene gas.

Although several embodiments have been described above, various modifications may be made as far as the same effects can be achieved. For example, although a high-pressure mercury lamp has been taken as an example of a UV light source, any other light source such as a low-pressure mercury lamp or an excimer laser generator may be used as far as it generates UV light. Since an excimer laser beam has a short wavelength of, e.g., 172 nm, a damaged layer can be repaired by irradiation with excimer laser light for a shorter time. A combination of UV irradiation using an excimer laser generator and UV irradiation using a high-pressure mercury lamp is also presented.

ALCAP-S (registered trademark; porous silica from Asahi Kasei Corporation), SiLK (registered trademark; polyarylether from The Dow Chemical Company), FLARE (registered trademark; polyarylether from Allied Signal, Inc.), or the like can be used as the material for a low-dielectric-constant film other than NCS (registered trademark; porous silica from Catalysts & Chemicals Industries Co., Ltd.) cited in the embodiments. Since any of these low-dielectric-constant films contains C as a main component, the same effects can be achieved even if it is applied to the above embodiment, in which C is supplied at the time of UV irradiation.

A TaN film, a Ti film, a TiN film, a W film, a WN film, a Zr film, a ZrN film, or a film obtained by stacking these films can be used as a diffusion preventing film other than a Ta film cited in the embodiments. A Cu alloy, W, a W alloy, or the like can be used as a wiring material other than Cu.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device manufacturing method comprising:
depositing a first insulating film over a semiconductor substrate;
etching a part of the first insulating film; and
performing UV irradiation to the first insulating film.

2. The semiconductor device manufacturing method according to claim 1, wherein
depositing the first insulating film over the semiconductor substrate comprises
forming a first wiring layer over the semiconductor substrate, and
depositing the first insulating film over the first wiring layer.

3. The semiconductor device manufacturing method according to claim 1, wherein
etching the part of the first insulating film comprises
depositing a photoresist over the first insulating film,
patterning the photoresist,
etching the part of the first insulating film, and ashing the patterned photoresist.

4. The semiconductor device manufacturing method according to claim 1, further comprising, after performing the UV irradiation to the first insulating film, forming a second wiring layer.

5. The semiconductor device manufacturing method according to claim 1, wherein the first insulating film is a film which includes an insulating material with a relative dielectric constant lower than a relative dielectric constant of SiO₂.

6. The semiconductor device manufacturing method according to claim 1, wherein the first insulating film includes an insulating material which contains C.

7. The semiconductor device manufacturing method according to claim 6, wherein the first insulating film is one or more of the group consisting of a polyarylene film, a polyarylether film, a hydrogen silsesquioxane film, a methyl silsesquioxane film, a silicon carbide film, a porous silica film, and a film which is a hybrid of at least two of the films and a film obtained by stacking at least two members of the group.

8. The semiconductor device manufacturing method according to claim 1, further comprising, after etching the part of the first insulating film and before performing the UV irradiation, performing a process using vapor of an organic solvent to the first insulating film.

9. The semiconductor device manufacturing method according to claim 8, wherein the organic solvent has a methyl group.

10. The semiconductor device manufacturing method according to claim 9, wherein the organic solvent includes at least one of the group consisting of dimethylaminotrimethylsilane, hexamethyldisilazane, tetramethydisilazane, divinyltetramethyldisilazane, cyclic dimethylsilazane, and heptamethyldisilazane.

11. The semiconductor device manufacturing method according to claim 1, wherein the UV irradiation is performed in an inert atmosphere.

12. The semiconductor device manufacturing method according to claim 11, wherein the inert atmosphere comprises a gas which includes at least one of the group consisting of He gas, Ar gas, and N₂ gas.

13. The semiconductor device manufacturing method according to claim 1, wherein the UV irradiation is performed using UV light which has wavelengths ranging from 150 nm to 400 nm.

14. The semiconductor device manufacturing method according to claim 1, wherein the UV irradiation is performed using, as a light source, at least one of the group consisting of a high-pressure mercury lamp, a low-pressure mercury lamp, and an excimer laser generator.

15. The semiconductor device manufacturing method according to claim 1, wherein
performing the UV irradiation of the first insulating film comprises
a first irradiation step to be performed using an excimer laser generator as a light source, and
a second irradiation step to be performed using a high-pressure mercury lamp as a light source.

16. The semiconductor device manufacturing method according to claim 1, wherein the UV irradiation is performed while a temperature of the semiconductor substrate is kept at 25° C. to 300° C.

17. The semiconductor device manufacturing method according to claim 1, wherein said etching the part of the first insulating film forms a wiring trench in the first insulating film.

18. The semiconductor device manufacturing method according to claim 17, further comprising, after performing the UV irradiation, depositing a diffusion preventing film in the wiring trench.

19. A semiconductor device manufacturing method comprising:
depositing a first insulating film over a semiconductor substrate;
depositing a photoresist over the first insulating film,
patterning the photoresist;
etching a part of the first insulating film;
ashing the patterned photoresist;
performing a process of applying vapor of an organic solvent to the first insulating film; and
performing UV irradiation to the first insulating film.

20. The semiconductor device manufacturing method according to claim 19, wherein the organic solvent includes at least one of the group consisting of dimethylaminotrimethylsilane, hexamethyldisilazane, tetramethydisilazane, divinyltetramethyldisilazane, cyclic dimethylsilazane, and heptamethyldisilazane.
